(19) United States
(12) Patent Application Publication
(10) Pub. No.: US 2025/0370026 A1
(43) Pub. Date: Dec. 4, 2025

(54) LINK-SIDE INSULATION MEASUREMENT

(71) Applicant: VISTEON GLOBAL TECHNOLOGIES, INC., Van Buren Township, MI (US)

(72) Inventors: Tao Wang, Oakland Township, MI (US); Mathew Breton, Westland, MI (US); Theodore Kim, Van Buren Township, MI (US); Kyungsu Bang, Van Buren Township, MI (US)

(73) Assignee: VISTEON GLOBAL TECHNOLOGIES, INC., Van Buren Township, MI (US)

(21) Appl. No.: 19/082,053

(22) Filed: Mar. 17, 2025

Related U.S. Application Data
(60) Provisional application No. 63/566,209, filed on Mar. 15, 2024.

(51) Int. Cl. G01R 31/12; G01R 19/165; G01R 27/02

(52) U.S. Cl. CPC G01R 31/1263; G01R 19/16576; G01R 27/025

(57) ABSTRACT

A circuit for measuring and managing voltage in an electrical system includes a low-impedance measurement circuit configured to perform high-speed voltage measurements when the voltage is less than 60V. A discharge circuit is configured to rapidly discharge Y-capacitance when the voltage is greater than 60V. A voltage detection circuit configured to measure a link voltage and determine whether the voltage exceeds 60V. A switching mechanism comprising at least one of a relay, stacked field-effect transistors (FETs), or a combination thereof, is configured to selectively isolate the low-impedance measurement circuit from chassis ground to ensure compliance with working and withstanding voltage requirements. A control circuit is configured to activate the discharge circuit if the measured link voltage exceeds 60V to reduce the voltage below 60V and enable the low-impedance measurement circuit once the voltage is within the safe operating range.

### CROSS-REFERENCE TO RELATED APPLICATIONS

This application claims the benefit of U.S. Provisional Application No. 63/566,209, filed Mar. 15, 2024, which is hereby incorporated by reference in its entirety.

### TECHNICAL FIELD

The present disclosure relates to measuring link-side insulation, such as in an electric vehicle.

### BACKGROUND

A measurement system may have a relatively limited operational voltage range if its circuit design has high leakage currents, mainly due to the high leakage currents tending to limit accuracy below a certain link voltage, such as 200 Volts (V) to 300V. Similarly, at least in some instances, the circuit design may also have high impedance, which may in turn limit the speed of the measurements and calculation such that high-speed insulation measurements may be limited or practically impossible. The speed limitation may be due to the high Y-Capacitance of link-side systems combining with the high-impedance nature of the circuit, which tends to increase capacitor charging/discharging times.

### SUMMARY

In one aspect of the disclosure, a circuit for measuring and managing voltage in an electrical system includes a low-impedance measurement circuit configured to perform high-speed voltage measurements when the voltage is less than 60V. A discharge circuit is configured to rapidly discharge Y-capacitance when the voltage is greater than 60V. A voltage detection circuit configured to measure a link voltage and determine whether the voltage exceeds 60V. A switching mechanism comprising at least one of a relay, stacked field-effect transistors (FETs), or a combination thereof, is configured to selectively isolate the low-impedance measurement circuit from chassis ground to ensure compliance with working and withstanding voltage requirements. A control circuit is configured to activate the discharge circuit if the measured link voltage exceeds 60V to reduce the voltage below 60V and enable the low-impedance measurement circuit once the voltage is within the safe operating range.

In one aspect of the disclosure, the switching mechanism includes two relays in series to prevent single-point failures and enhance safety.

In one aspect of the disclosure, the discharge circuit is activated only after the voltage detection circuit confirms that the link voltage exceeds 60V.

In one aspect of the disclosure, the low-impedance measurement circuit is configured to calculate high-speed insulation resistance.

In one aspect of the disclosure, the switching mechanism comprises a relay that forms a high-voltage barrier between the low-impedance circuit and chassis ground.

In one aspect of the disclosure, a control system is configured to dynamically switch between the low-impedance measurement circuit and the discharge circuit based on real-time voltage measurements.

In one aspect of the disclosure, the stacked FETs are arranged to reduce leakage current and improve voltage accuracy.

In another aspect of the disclosure, a method for measuring and managing voltage in an electrical system includes measuring a link voltage using a voltage detection circuit to determine whether the voltage exceeds a threshold of 60V. The method includes activating a discharge circuit to reduce the voltage below 60V by discharging Y-capacitance if the measured voltage exceeds 60V, enabling a low-impedance measurement circuit to perform high-speed voltage measurements once the voltage is reduced below 60V, selectively isolating the low-impedance measurement circuit from chassis ground using at least one of a relay, stacked field-effect transistors (FETs), or a combination thereof, to ensure compliance with working and withstanding voltage requirements, and dynamically controlling the operation of the discharge circuit and low-impedance measurement circuit based on real-time voltage measurements to optimize accuracy and response time.

The above features and advantages and other features and advantages of the present teachings are readily apparent from the following detailed description of the best modes for carrying out the teachings when taken in connection with the accompanying drawings.

### BRIEF DESCRIPTION OF THE DRAWINGS

FIG. 1 illustrates a schematic block diagram of an exemplary first circuit having high current leakage and impedance with limited speed.

FIG. 2 illustrates a schematic block diagram of a portion of the exemplary first circuit as shown in FIG. 1.

FIG. 3 illustrates a schematic block diagram of another portion of the exemplary first circuit as shown in FIG. 1.

FIG. 4 illustrates a schematic block diagram of an exemplary second circuit having low current leakage and impedance with limited speed.

FIG. 5 illustrates a schematic block diagram of a portion of the exemplary second circuit as shown in FIG. 4.

FIG. 6 illustrates a schematic block diagram of another portion of the exemplary second circuit as shown in FIG. 4.

FIG. 7 illustrates a schematic block diagram of a subcircuit arrangement of the exemplary second circuit as shown in FIG. 4.

FIG. 8 illustrates a schematic block diagram of another subcircuit arrangement of the exemplary second circuit as shown in FIG. 4.

FIG. 9 illustrates a schematic block diagram of yet another subcircuit arrangement of the exemplary second circuit as shown in FIG. 4.

The present disclosure may have various modifications and alternative forms, and some representative embodiments are shown by way of example in the drawings and will be described in detail herein. Novel aspects of this disclosure are not limited to the particular forms illustrated in the above-enumerated drawings. Rather, the disclosure is to cover modifications, equivalents, and combinations falling within the scope of the disclosure as encompassed by the appended claims.

### DETAILED DESCRIPTION

As required, detailed embodiments of the present disclosure may be disclosed herein; however, it may be understood that the disclosed embodiments may be merely exemplary of the disclosure that may be embodied in various and alternative forms. The figures may not be necessarily to scale; some features may be exaggerated or minimized to show details of particular components. Therefore, specific structural and functional details disclosed herein may need not to be interpreted as limiting, but merely as a representative basis for teaching one skilled in the art to variously employ the present disclosure.

One aspect of the present disclosure relates to a circuit and method to optimize performance of a link-side measurement feature through more accurate measurements, faster measurements, and increased measurement range.

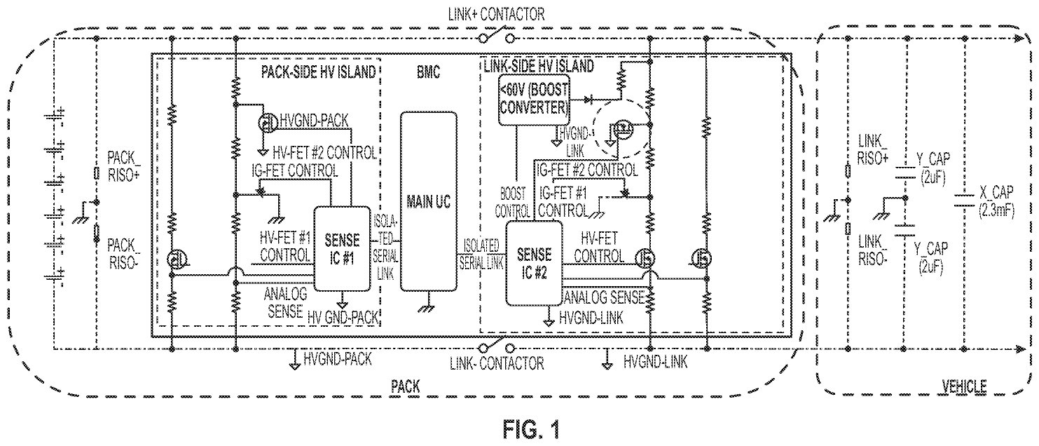

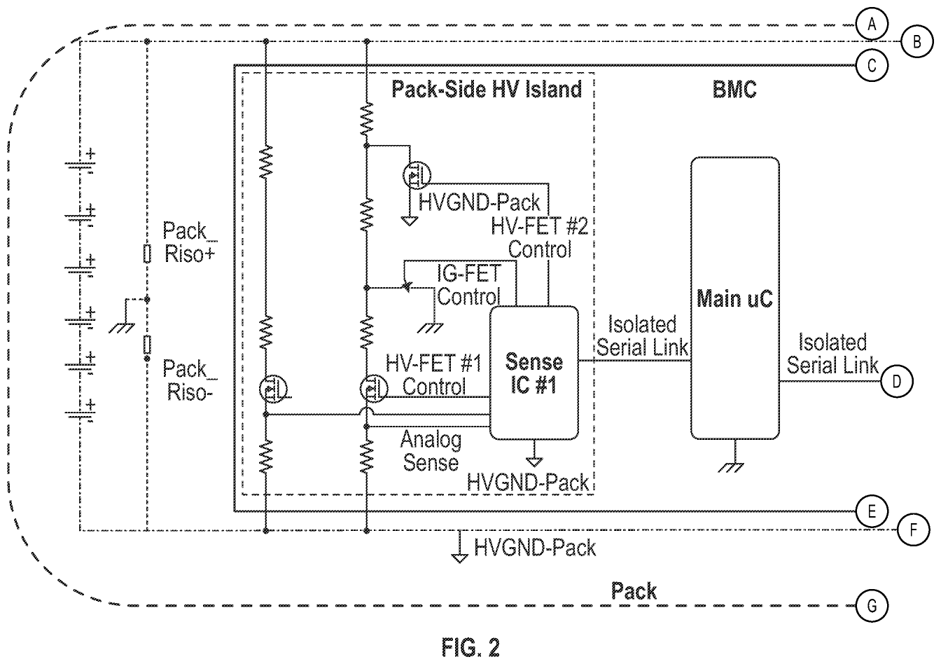

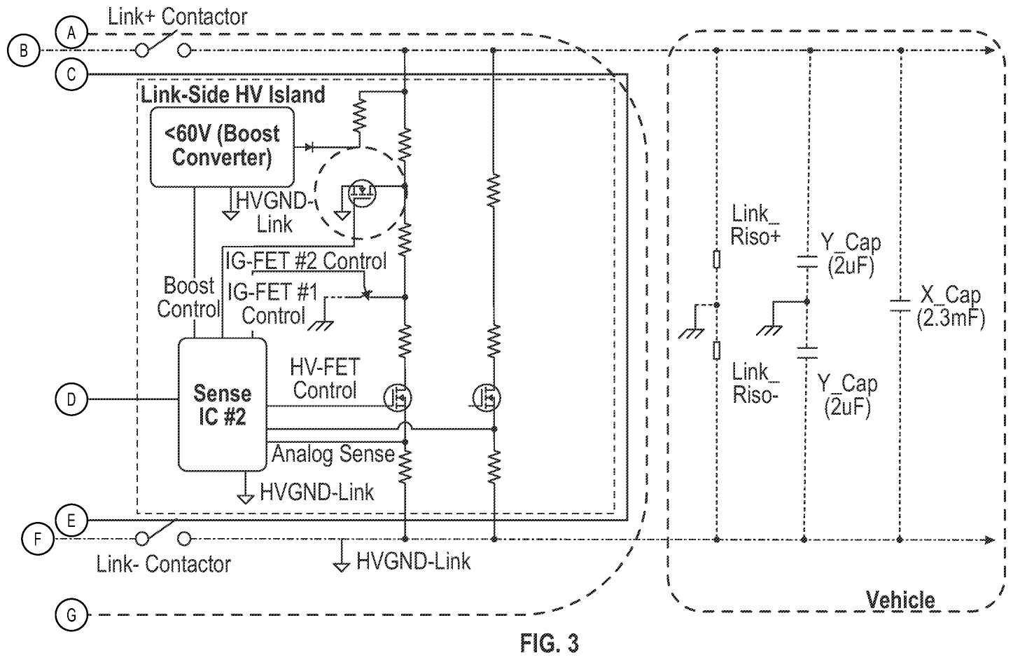

FIGS. 1-3 illustrate an exemplary first circuit design having high current leakage and impedance with limited speed.

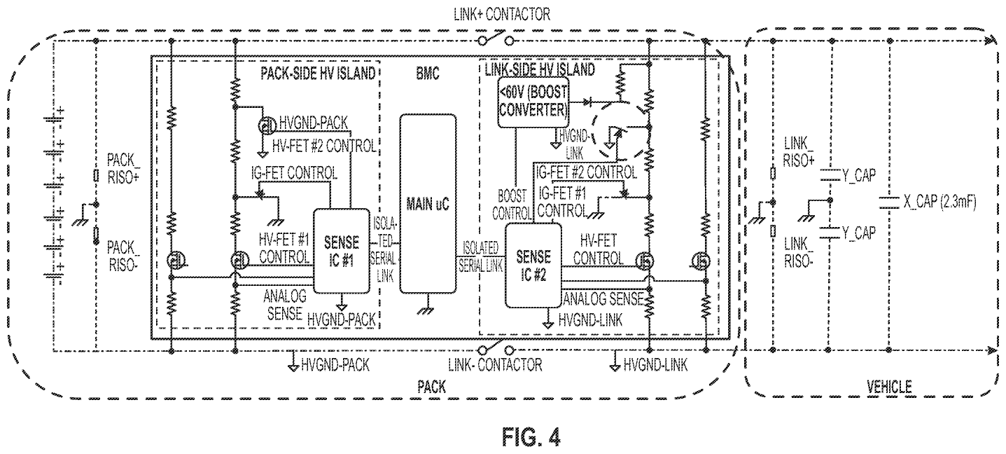

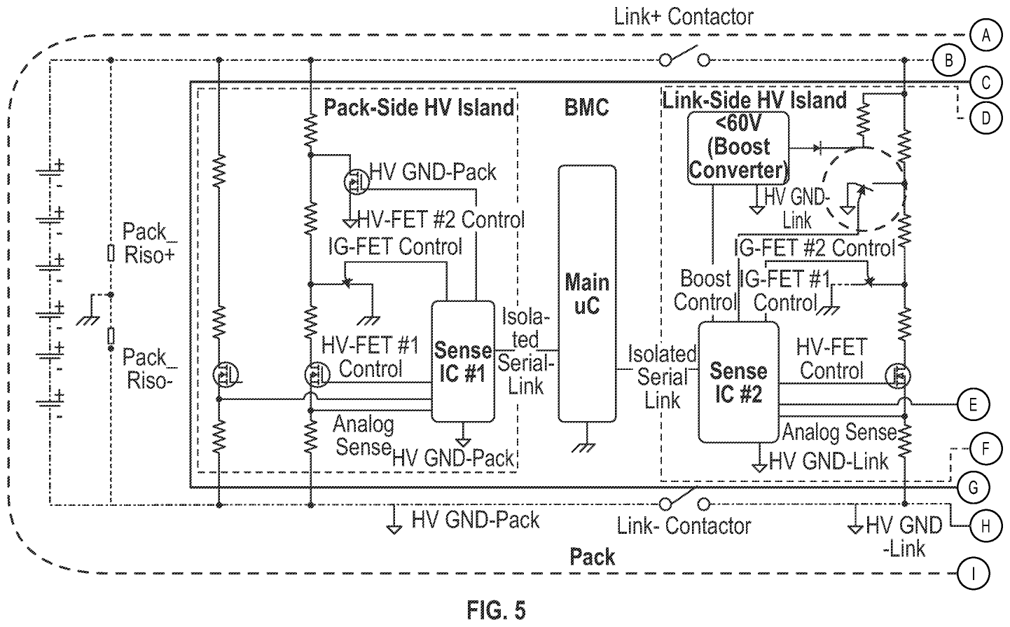

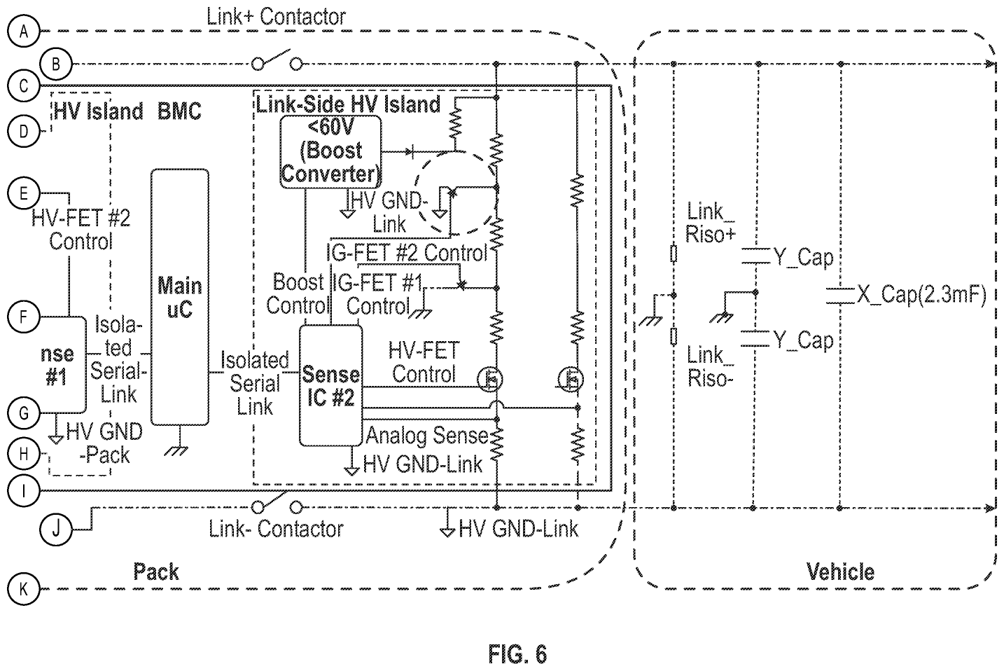

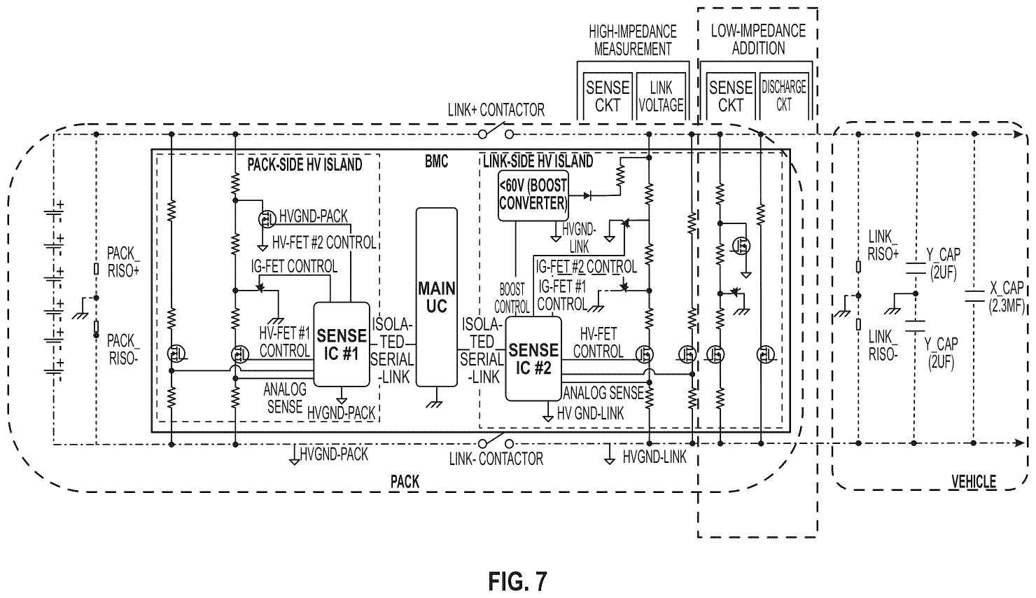

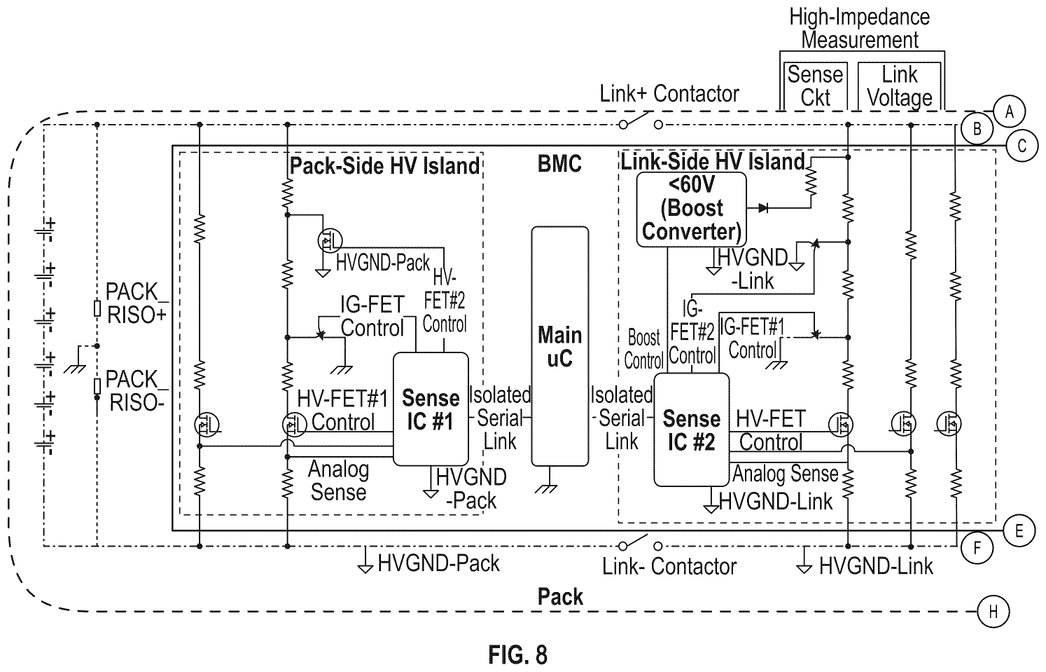

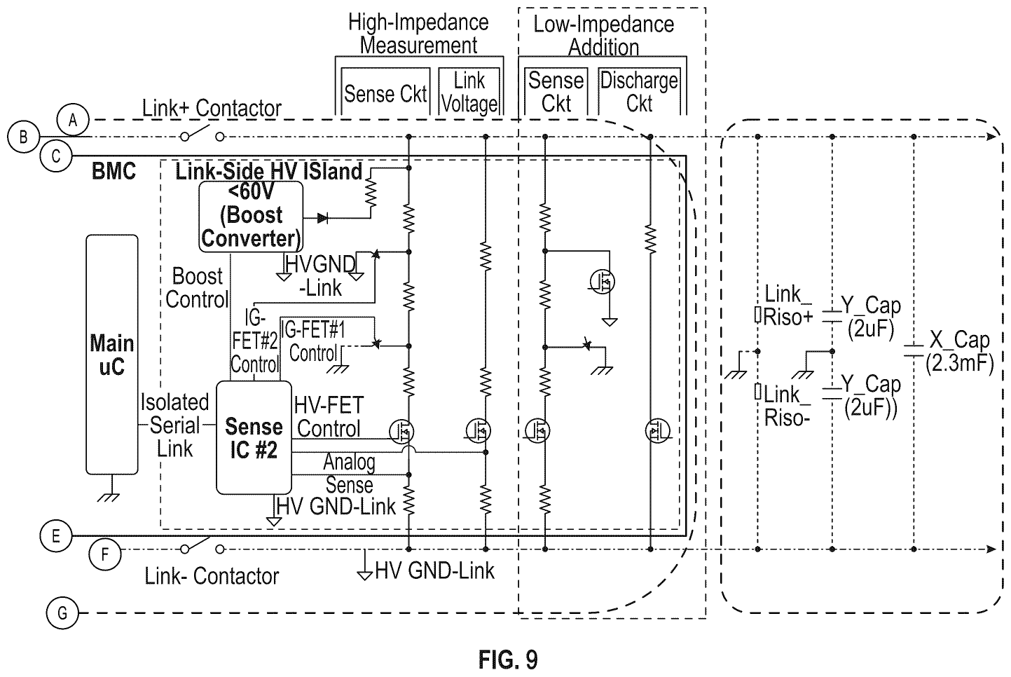

FIGS. 4-6 illustrate an exemplary second circuit design having less current leakage and/or impedance with optimized speed. The second circuit design may include addition of circuits and methods to perform a separate high-speed insulation measurement, optionally in <5 seconds, by reducing the current leakage through the device shown circled when it is off. The second circuit design facilitate fast-measurement invention with two subcircuits. These subcircuits are shown in the dashed outline box of FIGS. 7-9, with one optionally being a low-impedance version and the other being a fast discharge circuit.

A circuit 10 for measuring and managing voltage in an electrical system includes a low-impedance measurement circuit configured to perform high-speed voltage measurements when the voltage is less than 60V. A discharge circuit is configured to rapidly discharge Y-capacitance when the voltage is greater than 60V. A voltage detection circuit configured to measure a link voltage and determine whether the voltage exceeds 60V. A switching mechanism comprising at least one of a relay, stacked field-effect transistors (FETs), or a combination thereof, is configured to selectively isolate the low-impedance measurement circuit from chassis ground to ensure compliance with working and withstanding voltage requirements. A control circuit is configured to activate the discharge circuit if the measured link voltage exceeds 60V to reduce the voltage below 60V and enable the low-impedance measurement circuit once the voltage is within the safe operating range.

In one aspect of the disclosure, the switching mechanism includes two relays in series to prevent single-point failures and enhance safety. In another aspect of the disclosure, the discharge circuit is activated only after the voltage detection circuit confirms that the link voltage exceeds 60V. In yet another aspect of the disclosure, the low-impedance measurement circuit is configured to calculate high-speed insulation resistance.

In one aspect of the disclosure, the switching mechanism comprises a relay that forms a high-voltage barrier between the low-impedance circuit and chassis ground. In another aspect of the disclosure, a control system is configured to dynamically switch between the low-impedance measurement circuit and the discharge circuit based on real-time voltage measurements. In yet another aspect of the disclosure, the stacked FETs are arranged to reduce leakage current and improve voltage accuracy.

A method for measuring and managing voltage in an electrical system includes measuring a link voltage using a voltage detection circuit to determine whether the voltage exceeds a threshold of 60V. The method includes activating a discharge circuit to reduce the voltage below 60V by discharging Y-capacitance if the measured voltage exceeds 60V, enabling a low-impedance measurement circuit to perform high-speed voltage measurements once the voltage is reduced below 60V, selectively isolating the low-impedance measurement circuit from chassis ground using at least one of a relay, stacked field-effect transistors (FETs), or a combination thereof, to ensure compliance with working and withstanding voltage requirements, and dynamically controlling the operation of the discharge circuit and low-impedance measurement circuit based on real-time voltage measurements to optimize accuracy and response time.

One aspect to the low-impedance circuit may be understood with respect to the isolation to chassis-ground, which may be included so that this circuit can meet both working and withstanding voltages. Due to the low-impedance nature of the circuit, avalanche conditions may be avoided to ensure protection to both the circuit. The second circuit design may include a high-voltage relay to ensure no leakage current is done, and optionally, if the safety required no single-point failures, two relays in series may be used.

Various aspect of the present disclosure may include:
Improved voltage range and accuracy by reducing leakage through intermediary FET by replacing it with either a relay, or stacked FETs, or a combination of a relay and FET or FETs.
A low-impedance measurement circuit used for fast measurements when the voltage is less 60V.
A fast-discharge circuit that will discharge the BMC Y-Capacitance if the voltage is >60V.
A method of measuring the link voltage first to determine if the voltage is >60V, and activating the discharge circuit to lower the voltage to >60V.
A method of using a low-impedance measurement circuit to calculate high-speed insulation.
A method of using a relay to create a high-voltage barrier between the low-impedance circuit and chassis ground.
A method of combining the link voltage measurement circuit with the discharge circuit with the low-impedance circuit to create a measurement when the link voltage is either >60V or <60V.

The present disclosure may have various modifications and alternative forms, and some representative embodiments are shown by way of example in the drawings and will be described in detail herein. Novel aspects of this disclosure are not limited to the particular forms illustrated in the above-enumerated drawings. Rather, the disclosure is to cover modifications, equivalents, and combinations falling within the scope of the disclosure as encompassed by the appended claims.

While various embodiments have been described, the description is intended to be exemplary, rather than limiting and it will be apparent to those of ordinary skill in the art that many more embodiments and implementations are possible that are within the scope of the embodiments. Any feature of any embodiment may be used in combination with or substituted for any other feature or element in any other embodiment unless specifically restricted. Accordingly, the embodiments are not to be restricted except in light of the attached claims and their equivalents. Also, various modifications and changes may be made within the scope of the attached claims.

Although several modes for carrying out the many aspects of the present teachings have been described in detail, those familiar with the art to which these teachings relate will recognize various alternative aspects for practicing the present teachings that are within the scope of the appended claims. It is intended that all matter contained in the above description or shown in the accompanying drawings shall be interpreted as illustrative and exemplary of the entire range of alternative embodiments that an ordinarily skilled artisan would recognize as implied by, structurally and/or functionally equivalent to, or otherwise rendered obvious based upon the included content, and not as limited solely to those examples.

Those having ordinary skill in the art will recognize that terms such as “above,” “below,” “front,” “back,” “upward,” “downward,” “top,” “bottom,” etc., may be used descriptively herein without representing limitations on the scope of the disclosure. Furthermore, the present teachings may be described in terms of functional and/or logical block components and/or various processing steps. Such block components may be comprised of various hardware components, software components executing on hardware, and/or firmware components executing on hardware.

The foregoing detailed description and the drawings are supportive and descriptive of the disclosure, but the scope of the disclosure is defined solely by the claims. As will be appreciated by those of ordinary skill in the art, various alternative designs and embodiments may exist for practicing the disclosure defined in the appended claims.

What is claimed is:

1. A circuit for measuring and managing voltage in an electrical system, comprising:
a low-impedance measurement circuit configured to perform high-speed voltage measurements when the voltage is less than 60V;
a discharge circuit configured to rapidly discharge Y-capacitance when the voltage is greater than 60V;
a voltage detection circuit configured to measure a link voltage and determine whether the voltage exceeds 60V;
a switching mechanism comprising at least one of a relay, stacked field-effect transistors (FETs), or a combination thereof, configured to selectively isolate the low-impedance measurement circuit from chassis ground to ensure compliance with working and withstanding voltage requirements; and
a control circuit configured to:
activate the discharge circuit if the measured link voltage exceeds 60V to reduce the voltage below 60V; and
enable the low-impedance measurement circuit once the voltage is within the safe operating range.

2. The circuit of claim 1 wherein the switching mechanism includes two relays in series to prevent single-point failures and enhance safety.

3. The circuit of claim 1 wherein the discharge circuit is activated only after the voltage detection circuit confirms that the link voltage exceeds 60V.

4. The circuit of claim 1 wherein the low-impedance measurement circuit is configured to calculate high-speed insulation resistance.

5. The circuit of claim 1 wherein the switching mechanism comprises a relay that forms a high-voltage barrier between the low-impedance circuit and chassis ground.

6. The circuit of claim 1 further comprising a control system configured to dynamically switch between the low-impedance measurement circuit and the discharge circuit based on real-time voltage measurements.

7. The circuit of claim 1 wherein the stacked FETs are arranged to reduce leakage current and improve voltage accuracy.

8. A method for measuring and managing voltage in an electrical system, comprising:
measuring a link voltage using a voltage detection circuit to determine whether the voltage exceeds a threshold of 60V;
activating a discharge circuit to reduce the voltage below 60V by discharging Y-capacitance if the measured voltage exceeds 60V;
enabling a low-impedance measurement circuit to perform high-speed voltage measurements once the voltage is reduced below 60V;
selectively isolating the low-impedance measurement circuit from chassis ground using at least one of a relay, stacked field-effect transistors (FETs), or a combination thereof, to ensure compliance with working and withstanding voltage requirements; and
dynamically controlling the operation of the discharge circuit and low-impedance measurement circuit based on real-time voltage measurements to optimize accuracy and response time.
